(19) United States
(12) Patent Application Publication
(10) Pub. No.: US 2024/0377744 A1
(43) Pub. Date: Nov. 14, 2024

(54) LOCAL SHADOW MASKING FOR MULTI-COLOR EXPOSURES

(71) Applicant: Geminatio, Inc., Schenectady, NY (US)

(72) Inventors: Brennan Peterson, Longmont, CO (US); Phillip D. Hustad, Longmont, CO (US)

(73) Assignee: Geminatio, Inc., Schenectady, NY (US)

(21) Appl. No.: 18/696,593

(22) PCT Filed: Oct. 25, 2022
(86) PCT No.: PCT/US2022/047662

§ 371 Date: Mar. 28, 2024

Related U.S. Application Data
(60) Provisional application No. 63/271,881, filed on Oct. 26, 2021.

(51) Int. Cl. G03F 7/09; G03F 7/00; G03F 7/004; G03F 7/038; G03F 7/039; G03F 7/20

(52) U.S. Cl. CPC G03F 7/094; G03F 7/0035; G03F 7/0042; G03F 7/0382; G03F 7/0392; G03F 7/2004; G03F 7/2022; G03F 7/70033; G03F 7/70466

(57) ABSTRACT

A method of patterning a substrate includes providing a first photoresist on a substrate, layering a second photoresist on the first photoresist, exposing the second photoresist to a first pattern of actinic radiation, and developing the second photoresist such that portions of the second photoresist are dissolved providing gaps between features of the second photoresist, wherein the gaps uncover portions of the first photoresist. Then, the method includes exposing the first photoresist to a second pattern of actinic radiation and developing the first photoresist such that portions of the uncovered portions of the first photoresist are dissolved providing gaps between the features of the first photoresist where a portion of the substrate is exposed.

### BACKGROUND

Microfabrication of semiconductor devices includes various steps such as film deposition, pattern formation, and pattern transfer. Materials and films are deposited on a substrate by spin coating, vapor deposition, and other deposition processes. Pattern formation is typically performed by exposing a photo-sensitive film, known as a resist, to a pattern of actinic radiation and subsequently developing the resist to form a relief pattern. The relief pattern then acts as an etch mask, which, when one or more etching processes are applied to the substrate, cover portions of the substrate that are not to be etched.

Multi-patterning is a term that describes using more than one lithography step to create a final pattern. Multi-pattering, in different forms, enables the production of advanced semiconductor devices. Patterning typically includes two fundamental steps. The first step includes using lithography to create a pattern using mask-based exposure of light followed by development of soluble regions. The second step includes transferring the pattern into an underlying material by directional or anisotropic etching. These two steps together may be referred to as patterning a device.

To make advanced devices, a number of patterning steps may be used. For example, an area may be patterned with some form of multi-patterning, and then cut between one or more patterned regions using a cut mask. Subsequent “bridging” of active areas with a linking pattern may provide an advanced device. Often, providing such pattern structure mat take up to five, or even 6, exposures, which do not interact, e.g., a bridge should not break the isolation of a different area. As such, to provide these patterning structures, elaborate multi-step patterning processed have been developed. However, such processes are complex, expensive, and difficult to convert at each step of the patterning process. Accordingly, there exists a need to simplify the steps of conventional multi-step patterning processes thus providing better throughput, time, and ultimately, shrink capability.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a method of patterning a substrate that includes providing a first photoresist on a substrate, layering a second photoresist on the first photoresist, exposing the second photoresist to a first pattern of actinic radiation, and developing the second photoresist such that portions of the second photoresist are dissolved providing gaps between features of the second photoresist, wherein the gaps uncover portions of the first photoresist. Then, the method includes exposing the first photoresist to a second pattern of actinic radiation, and developing the first photoresist such that portions of the uncovered portions of the first photoresist are dissolved providing gaps between the features of the first photoresist where a portion of the substrate is exposed.

Other aspects and advantages of the claimed subject matter will be apparent from the following description and the appended claims.

### BRIEF DESCRIPTION OF DRAWINGS

FIGS. 1A-B are schematic illustrations of a pattern of actinic radiation that may be applied in a method in accordance with one or more embodiments of the present disclosure.

FIG. 2 is a block-flow diagram of a method in accordance with one or more embodiments of the present disclosure.

FIGS. 3A-3G are schematic illustrations of coated substrates at respective points of a method in accordance with one or more embodiments the present disclosure.

### DETAILED DESCRIPTION

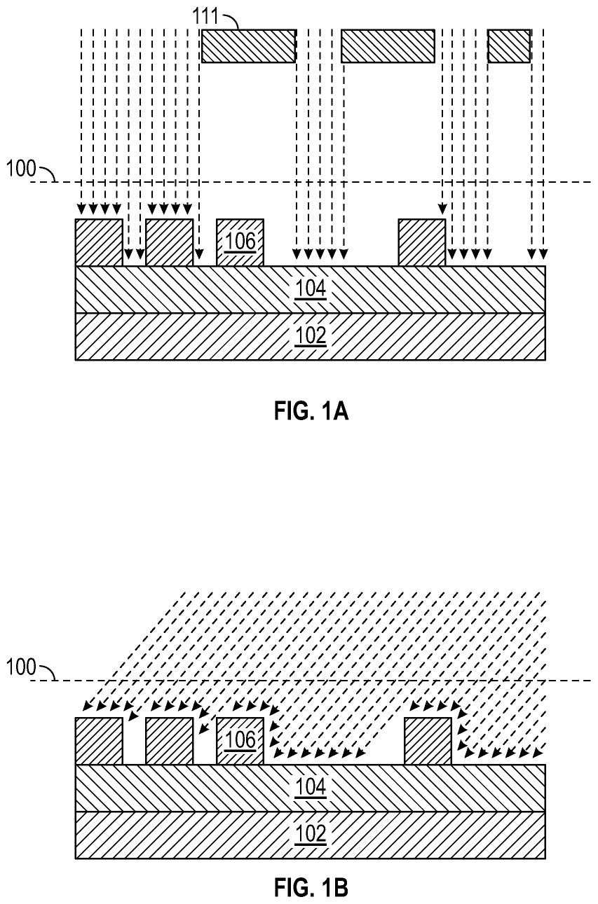

The present disclosure generally relates to a method of patterning a semiconductor substrate. Herein, the terms “semiconductor substrate” and “substrate” are used interchangeably, and may be any semiconductor material including, but not limited to, semiconductor wafers, semiconductor material layers, and combinations thereof. Methods in accordance with the present disclosure may combine conventional semiconductor masks with surface shadow masks or surface contact masks to achieved advanced semiconductor patterning. In one or more embodiments, a pattern of actinic radiation that reaches a layer of photoresist may be defined by the combination of a photomask and a contact mask. In such embodiments, the actinic radiation may be directed to the layer of photoresist at a perpendicular angle, with respect to a nominal plane defined by the substrate. A conventional photomask restricts or filters the actinic radiation, providing an initial pattern of actinic radiation that is further defined by the contact mask. Contact patterns or surface patterns are relief patterns or mask patterns or templates formed in contact with a surface of the wafer. Accordingly, there is direct filtering of light with such a mask. The contact mask may be an existing relief pattern provided over the target layer of photoresist. FIG. 1A shows the pattern of actinic radiation that may be applied to a layer of photoresist 104 on a substrate 102 using a combination of a photomask 111 and a contact mask. The contact mask is formed by the structures of a relief pattern of a second photoresist 106. The angle of the actinic radiation may be determined with respect to nominal plane 100 in FIG. 1A.

Alternatively, in one or more embodiments, a pattern of actinic radiation that reaches a layer of photoresist may be defined by the combination of a photomask and a surface shadow mask. A shadow mask may be created using an existing relief pattern over the target layer of photoresist, where the pattern of actinic radiation is directed to the layer of photoresist at an angle other than 90°, or perpendicular, with respect to a nominal plane defined by the substrate such that a shadow of the existing relief pattern is provided and dictates exposure to the actinic radiation. Creation of a surface shadow mask is beneficial when exposures can be separated. For extreme ultraviolet (“EUV”) light, with very low penetration depth, simple shadow masks can be locally created by using a second lithography step above the existing target EUV layer. FIG. 1B shows the pattern of actinic radiation that may be applied to a layer of photoresist 104 on a substrate 102 using a combination of a contact mask and surface shadow mask. The structures of relief pattern of a second photoresist 106 act as both the contact mask and the surface shadow mask. The angle of the pattern of acinic radiation may be determined with respect to plane 100 in FIG. 1B.

Such techniques provide patterning advantages. One benefit is taking advantage the 3D height of the surface contact mask, which can provide illumination control on the second exposure. For example, projecting light at an angle, such as 45°, with respect to the substrate, causes some light to get cut off because of shadowing. For angled exposure, a scanner can be set to mono pole on one side of the lens stack when interference of light is not needed. Normally, constructive and destructive interference is needed but can be suspended for some angled exposures.

The structures from the surface contact mask can function as a filter for a projected pattern. From a top-down perspective with light perpendicular to the surface of the substrate, narrow features can be exposed. A filter in Fourier domain is provided, a numerical aperture filter. A given contact mask can be relatively tall compared to spaces that it defines. For spaces/trenches that have a width close to the height of lines, this means those trenches can be completely shadowed by angled light. And then for incident light, the lines provide a mechanism to cut off undesirable portions of given projected patterns.

Methods disclosed herein can improve the function of EUV photolithography. During exposure of an EUV resist, the EUV source primarily provides radiation at 13.5 nm. However, EUV sources also produce out-of-band radiation, including UV light and DUV light, in an amount of about 5% in addition to the EUV radiation. Such radiation, especially between 190 and 240 nm, may lead to a reduction in sensitivity of an EUV resist of the deterioration of a pattern shape. In particular, a pattern shape having a line width of 22 nm or less being to be affected by this out-of-band radiation, which adversely effects the resolution of an EUV resist.

Techniques herein can assist in filtering out-of-band radiation and improve pattern shape and resolution in EUV photolithography. Accordingly, the different parts of the secondary mask add capabilities to patterns. In the simplest case, the surface pattern creates dense areas that act as filters.

Method in accordance with the present disclosure provide access to small, and even sub-micron, features. Accordingly, methods disclosed herein may be used to generate high resolution features, filter incident light, and produce novel devices and forms.

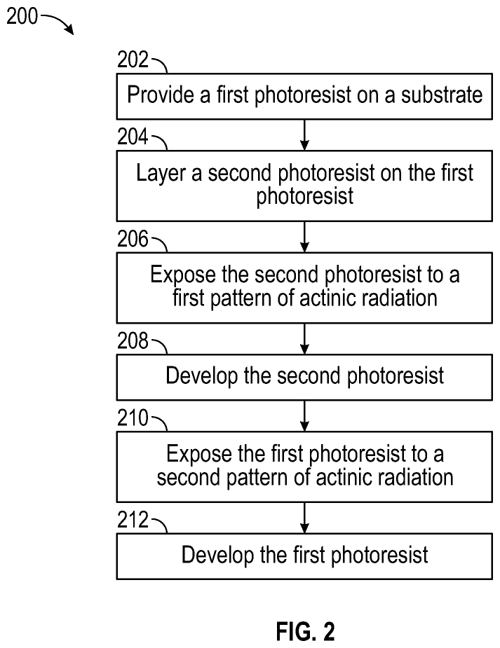

A method 200 in accordance with the present disclosure is shown in, and discussed with reference to, FIG. 2. Initially, method 200 includes, at block 202, providing a first photoresist on a substrate. Then, at block 204, a second photoresist is layered on the first photoresist. At block 206, the second photoresist is exposed to a pattern of actinic radiation, and at block 208 the second photoresist is developed to provide a relief pattern. Then, at block 210, the first photoresist is exposed to a second pattern of actinic radiation, using the relief pattern on the second photoresist as a contact mask. Finally, the first photoresist is developed at block 212.

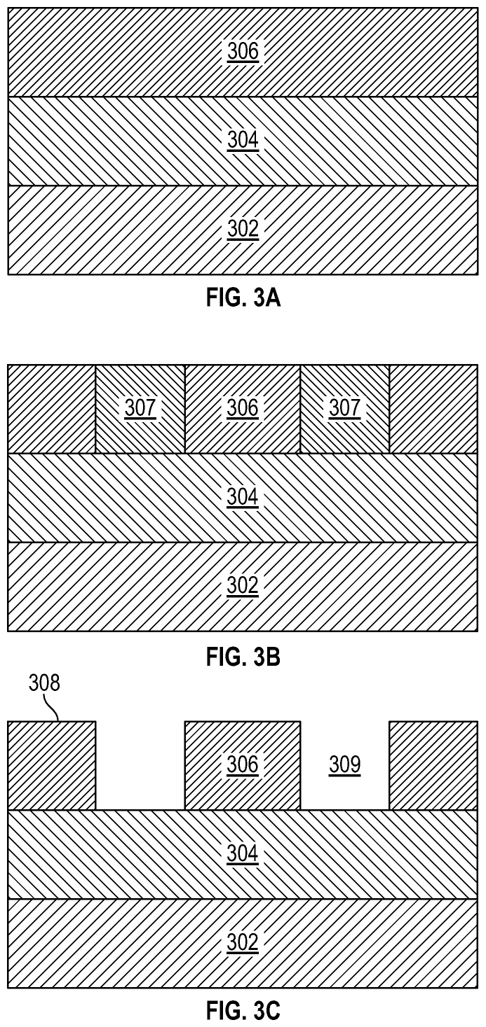

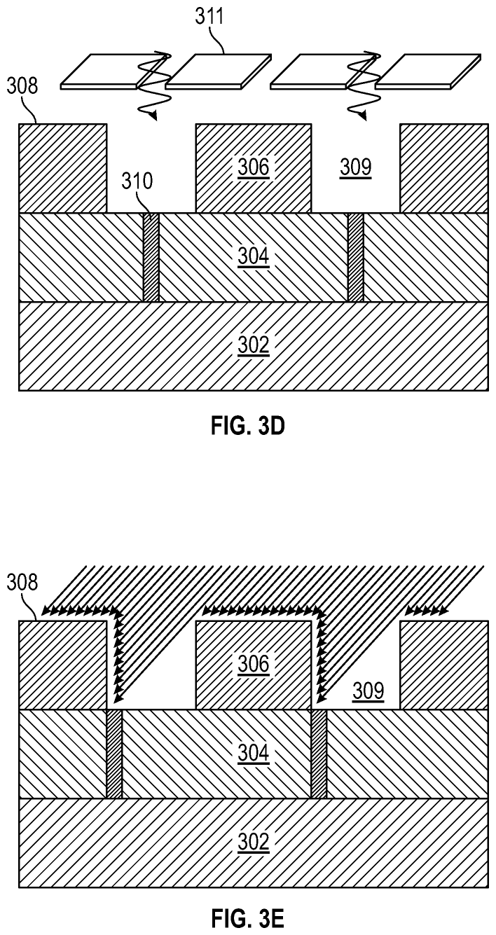

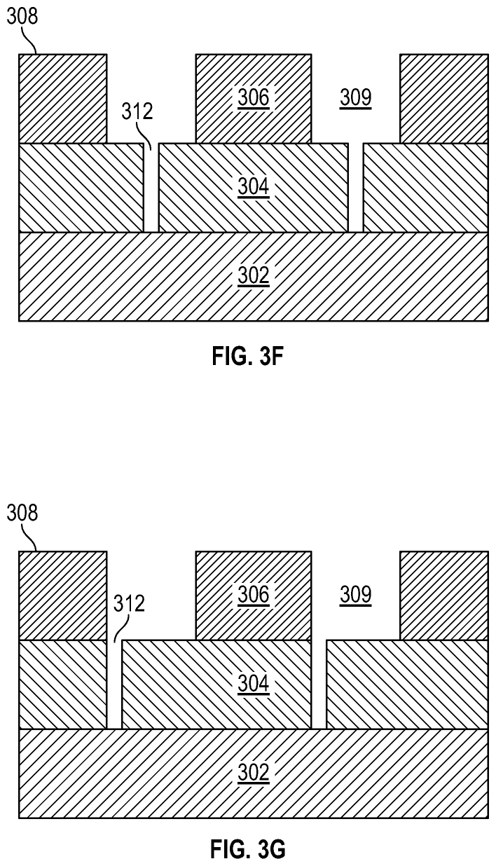

Schematic depictions of a coated substrate at various points during the method described above are shown in FIGS. 3A-G. Herein “a coated substrate” refers to a substrate that is coated with one or more layers, such as a first photoresist layer and a second photoresist layer. FIG. 3A shows a substrate 302 including a layer of a first photoresist 304 underneath a layer of a second photoresist 306. In FIG. 3B, the second resist is exposed to a pattern of actinic radiation to provide two portions, an unexposed portion 306 and an exposed portion 307, of the second photoresist. FIG. 3C shows a coated substrate after the second photoresist has been developed, such that regions of the first photoresist are exposed by gaps 309 between features 308 of second photoresist 306. In FIG. 3D, a coated substrate in which portions 310 of the first photoresist have been exposed to a second pattern of actinic radiation with pattern provided by photomask 311 is shown. Finally, FIG. 3F shows a coated substrate 302 after the first photoresist 304 has been developed, such that portions of the substrate are exposed and able to be etched. FIG. 3E and FIG. 3G show variations from FIGS. 3D and 3F, respectively when the actinic radiation is incident at an angle. The method of FIG. 2 and coated substrates shown in FIGS. 3A-G are discussed in detail below.

In one or more embodiments, the substrate that is to be patterned according to the disclosed method may include a target layer. Any suitable target layer known in the art may be layered on the substrate. In particular embodiments, the target layer is a hardmask layer.

At block 202 of method 200, a first photoresist is provided on the substrate. In one or more embodiments, the first photoresist is an EUV resist, where the term EUV resist denotes a resist sensitive to EUV light. Suitable EUV resists include a chemically amplified resist, a metal organic resist, and a dry resist.

In one or more embodiments, the EUV resist is a chemically amplified photosensitive composition that comprises a polymer, a photoacid generator, and a solvent. In one or more embodiments, the first photoresist includes a polymer. The polymer may be any standard polymer typically used in photoresist material and may particularly be a polymer having acid-labile groups. For example, the polymer may be a polymer made from monomers including vinyl aromatic monomers such as styrene and p-hydroxystyrene, acrylate, methacrylate, norbornene, and combinations thereof. Monomers that include reactive functional groups may be present in the polymer in a protected form. For example, the —OH group of p-hydroxystyrene may be protected with a tert-butyloxycarbonyl protecting group. Such protecting group may alter the reactivity and solubility of the polymer included in the first photoresist. As will be appreciated by one of ordinary skill in the art, various protecting groups may be used for this reason. Acid-labile groups include, for example, tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-decomposable groups”, “acid-cleavable groups,” “acid-cleavable protecting groups,” “acid-labile protecting groups,” “acid-leaving groups,” and “acid-sensitive groups.”

The acid-labile group may, on decomposition, form a carboxylic acid on the polymer. Such acid-labile group is preferably a tertiary ester group of the formula —C(O)OC(R1)3 or an acetal group of the formula —C(O)OC(R2)2OR3, wherein: R1 is each independently linear C1-20 alkyl, branched C3-20 alkyl, monocyclic or polycyclic C3-20 cycloalkyl, linear C2-20 alkenyl, branched C3-20 alkenyl, monocyclic or polycyclic C3-20 cycloalkenyl, monocyclic or polycyclic C6-20 aryl, or monocyclic or polycyclic C2-20 heteroaryl, preferably linear C1-6 alkyl, branched C3-6 alkyl, or monocyclic or polycyclic C3-10 cycloalkyl, each of which is substituted or unsubstituted, each R1 optionally including as part of its structure one or more groups chosen from —O—, —C(O)—, —C(O)—O—, or —S—, and any two R1 groups together optionally forming a ring; R2 is independently hydrogen, fluorine, linear C1-20 alkyl, branched C3-20 alkyl, monocyclic or polycyclic C3-20 cycloalkyl, linear C2-20 alkenyl, branched C3-20 alkenyl, monocyclic or polycyclic C3-20 cycloalkenyl, monocyclic or polycyclic C6-20 aryl, or monocyclic or polycyclic C2-20 heteroaryl, preferably hydrogen, linear C1-6 alkyl, branched C3-6 alkyl, or monocyclic or polycyclic C3-10 cycloalkyl, each of which is substituted or unsubstituted, each R2 optionally including as part of its structure one or more groups chosen from —O—, —C(O)—, —C(O)—O—, or —S—, and the R2 groups together optionally forming a ring; and R3 is linear C1-20 alkyl, branched C3-20 alkyl, monocyclic or polycyclic C3-20 cycloalkyl, linear C2-20 alkenyl, branched C3-20 alkenyl, monocyclic or polycyclic C3-20 cycloalkenyl, monocyclic or polycyclic C6-20 aryl, or monocyclic or polycyclic C2-20 heteroaryl, preferably linear C1-6 alkyl, branched C3-6 alkyl, or monocyclic or polycyclic C3-10 cycloalkyl, each of which is substituted or unsubstituted, R3 optionally including as part of its structure one or more groups chosen from —O—, —C(O)—, —C(O)—O—, or —S—, and one R2 together with R3 optionally forming a ring. Such monomer is typically a vinyl aromatic, (meth)acrylate, or norbornyl monomer. The total content of polymerized units comprising an acid-decomposable group which forms a carboxylic acid group on the polymer is typically from 10 to 100 mole %, more typically from 10 to 90 mole % or from 30 to 70 mole %, based on total polymerized units of the polymer.

Alternatively, or in addition, the polymer may include, as polymerized, a monomer comprising an acid-labile group, the decomposition of which group forms an alcohol group or a fluoroalcohol group on the polymer. Suitable such groups include, for example, an acetal group of the formula —COC(R2)2OR3—, or a carbonate ester group of the formula —OC(O)O—, wherein R is as defined above. Such monomer is typically a vinyl aromatic, (meth)acrylate, or norbornyl monomer. If present in the polymer, the total content of polymerized units comprising an acid-decomposable group, the decomposition of which group forms an alcohol group or a fluoroalcohol group on the polymer, is typically from 10 to 90 mole %, more typically from 30 to 70 mole %, based on total polymerized units of the polymer.

In another embodiment, the polymer may be a polymer that contains a silicon-containing unit that can be chemically bonded to the polymeric material. In a preferred embodiment, the silicon-containing unit includes silicon-oxygen bonds. Resists that include such polymers may be referred to herein as “silicon-based resists.” Examples of silicon-containing resist are disclosed in U.S. Pat. Nos. 5,985,524, 6,444,408, 6,670,093; 6,596,830; as well as by Schaedeli et al., “Bilayer Resist Approach for 193 nm Lithography”, Proc. SPIE, Vol. 2724, pp. 344-354, 1996; and Kessel et al, “Novel Silicon-Containing Resists for EUV and 193 nm Lithography”, Proc. SPIE, Vol. 3678, pp. 214-220, 1999.

As described above, suitable EUV resists include a metal organic resist. Thus, in one or more embodiments, the first photoresist is a metalorganic or metal-based resist based on metal oxide chemistry, including metal oxo/hydroxo compositions that utilize radiation sensitive ligands to enable patterning with actinic radiation. One class of radiation-based resists use peroxo ligands as the radiation sensitive stabilization ligands. Peroxo based metal oxo-hydroxo compounds are described, for example, in U.S. Pat. No. 9.176,377B2 to Stowers et al., entitled “Patterned Inorganic Layers, Radiation Based Patterning Compositions and Corresponding Methods,” incorporated herein by reference. Related resist compounds are discussed in published U.S. patent application 2013/0224652A1 to Bass et al., entitled “Metal Peroxo Compounds With Organic Co-ligands for Electron Beam, Deep UV and Extreme UV Resist Applications,” incorporated herein by reference. An effective type of resists have been developed with alkyl ligands as described in U.S. Pat. No. 9.310,684B2 to Meyers et al., entitled “Organometallic Solution Based High Resolution Patterning Compositions,” published U.S. patent application 2016/0116839A1 to Meyers et al., entitled “Organometallic Solution Based High Resolution Patterning Compositions and Corresponding Methods,” and U.S. patent application Ser. No. 15/291,738 entitled “Organotin Oxide Hydroxide Patterning Compositions, Precursors, and Patterning”, all of which are incorporated herein by reference. Tin compositions are exemplified in these documents, and the data presented herein focuses on tin-based resists, although the Edge bead removal solutions described herein are expected to be effective for other metal-based resists described below.

With respect to the tin-based photoresists of particular interest, these photoresists are based on the chemistry of organometallic compositions represented by the formula RzSnO(2−(z/2)−(x/2))(OH)x where 0<z≤2 and 0<(z+x)≤4, in which R is a hydrocarbyl group with 1-31 carbon atoms. However, it has been found that at least some of the oxo/hydroxo ligands can be formed following deposition based on in situ hydrolysis based on compositions represented by the formula RnSnX4−n where n=1 or 2, in which X is a ligand with a hydrolysable M—X bond. In general, suitable hydrolysable ligands (X in RSnX3) may include alkynides RC≡C, alkoxides RO—, azides N3—, carboxylates RCOO—, halides and dialkylamides. Thus, in some embodiments all or a portion for the oxo-hydroxo compositions can be substituted with the Sn—X compositions or a mixture thereof. The R—Sn bonds generally are radiation sensitive and form the basis for the radiation processable aspect of the resist. But some of the RzSnO(2−(z/2)—(x/2))(OH)x composition can be substituted with MO((m/2)−1/2)(OH)x where 0<z≤2, 0<(z+w)≤4, m=formal valence of Mm+, 0≤l≤m, y/z=(0.05 to 0.6), and M=M′ or Sn, where M′ is a non-tin metal of groups 2-16 of the periodic table, and R is hydrocarbyl groups with 1-31 carbon atoms. Thus, the photoresist being processed during the edge bead rinse can comprise a selected blend of RzSnO(2−(z/2)−(x/2))(OH)x. R′nSnX4−n, and/or MO((m/2)−1/2)(OH)x, in which generally a significant fraction of the composition includes alkyl-tin bonds. Other photoresist compositions include, for example, compositions having metal carboxylate bonds (e.g., ligands of acetate, propanoate, butanoate, benzoate, and/or the like), such as dibutyltin diacetate.

While metal oxo/hydroxo or carboxylate-based photoresists referenced above are particularly desirable, some other high-performance photoresists may be suitable in some embodiments. Specifically, other metal-based photoresists include those with high etch selectivity to substrate and hardmask materials. These may include photoresists such as metal-oxide nanoparticle resists (e.g., Jiang, Jing; Chakrabarty, Souvik; Yu, Mufei; et al., “Metal Oxide Nanoparticle Resists for EUV Patterning”, Journal Of Photopolymer Science And Technology 27(5), 663-666 2014, incorporated herein by reference), or other metal containing resists (A Platinum-Fullerene Complex for Patterning Metal Containing Nanostructures, D. X. Yang, A. Frommhold, D. S. He, Z. Y. Li, R. E. Palmer, M. A. Lebedeva, T. W. Chamberlain, A. N. Khlobystov, A. P. G. Robinson, Proc SPIE Advanced Lithography, 2014, incorporated herein by reference). Other metal-based resists are described in published U.S. patent application 2009/0155546A1 to Yamashita et al., entitled “Film-Forming Composition, Method for Pattern Formation, and Three-Dimensional Mold,” and U.S. Pat. No. 6,566,276 to Maloney et al., entitled “Method of Making Electronic Materials,” both of which are incorporated herein by reference.

In other embodiments, the first photoresist is an EUV-sensitive film applied by a vapor deposition process, known as a “dry resist”. The film may be formed by mixing a vapor stream of an organometallic precursor with a vapor stream of a counter-reactant so as to form a polymerized organometallic material. The hardmask may also be formed by depositing the organometallic polymer-like material onto the surface of the semiconductor substrate. The mixing and depositing operations may be performed by chemical vapor deposition (CVD), atomic layer deposition (ALD), and ALD with a CVD component, such as a discontinuous, ALD-like process in which metal precursors and counter-reactants are separated in either time or space.

Such EUV-sensitive films comprise materials which, upon exposure to EUV, undergo changes, such as the loss of bulky pendant substituents bonded to metal atoms in low density M—OH rich materials, allowing their crosslinking to denser M—O—M bonded metal oxide materials. Through EUV patterning, areas of the film are created that have altered physical or chemical properties relative to unexposed areas. These properties may be exploited in subsequent processing, such as to dissolve either unexposed or exposed areas, or to selectively deposit materials on either the exposed or unexposed areas. In some embodiments, the unexposed film has a hydrophobic surface and the exposed film has a hydrophilic surface (it being recognized that the hydrophilic properties of exposed and unexposed areas are relative to one another) under the conditions at which such subsequent processing is performed. For example, the removal of material may be performed by leveraging differences in chemical composition, density and cross-linking of the film. Removal may be by wet processing or dry processing.

The thin films are, in various embodiments, organometallic materials, comprising SnOₓ or other metal oxides moieties. The organometallic compounds may be made in a vapor phase reaction of an organometallic precursor with a counter reactant. In various embodiments, the organometallic compounds are formed through mixing specific combinations of organometallic precursors having bulky alkyl groups or fluoroalkyl with counter-reactants and polymerizing the mixture in the vapor phase to produce a low-density, EUV-sensitive material that deposit onto the substrate.

In various embodiments, organometallic precursors comprise at least one alkyl group on each metal atom that can survive the vapor-phase reaction, while other ligands or ions coordinated to the metal atom can be replaced by the counter-reactants. Organometallic precursors include those of the formula:

MₐR_{b}L_{c} (Formula 1)

wherein: M is a metal with a high EUV absorption cross-section; R is alkyl, such as CₙH₂ₙ₊₁, preferably wherein n≥3; L is a ligand, ion or other moiety which is reactive with the counter reactant; a≥1; b≥1; and c≥1.

In various embodiments, M has an atomic absorption cross section equal to or greater than 1×10⁷ cm²/mol. M may be, for example, selected from the group consisting of tin, bismuth, antimony and combinations thereof. In some embodiments, M is tin. R may be fluorinated, e.g., having the formula CₙFₓH₍₂ₙ₊₁₎. In various embodiments, R has at least one beta-hydrogen or beta-fluorine. For example, R may be selected from the group consisting of i-propyl, n-propyl, t-butyl, i-butyl, n-butyl, sec-butyl, n-pentyl, i-pentyl, t-pentyl, sec-pentyl, and mixtures thereof. L may be any moiety readily displaced by a counter-reactant to generate an M—OH moiety, such as a moiety selected from the group consisting of amines (such as dialkylamino, monalkylamino), alkoxy, carboxylates, halogens, and mixtures thereof.

Organometallic precursors may be any of a wide variety of candidate metal-organic precursors. For example, where M is tin, such precursors include t-butyl tris(dimethylamino) tin, i-butyl tris(dimethylamino) tin, n-butyl tris(dimethylamino) tin, sec-butyl tris(dimethylamino) tin, i-propyl(tris)dimethylamino tin, n-propyl tris(diethylamino) tin, and analogous alkyl(tris)(t-butoxy) tin compounds such as t-butyl tris(t-butoxy) tin. In some embodiments, the organometallic precursors are partially fluorinated.

Counter-reactants preferably have the ability to replace the reactive moieties ligands or ions (e.g., L in Formula 1, above) so as to link at least two metal atoms via chemical bonding. Counter-reactants can include water, peroxides (e.g., hydrogen peroxide), di-or polyhydroxy alcohols, fluorinated di-or polyhydroxy alcohols, fluorinated glycols, and other sources of hydroxyl moieties. In various embodiments, a counter-reactant reacts with the organometallic precursor by forming oxygen bridges between neighboring metal atoms. Other potential counter-reactants include hydrogen sulfide and hydrogen disulfide, which can crosslink metal atoms via sulfur bridges.

The thin films may include optional materials in addition to an organometallic precursor and counter-reactants to modify the chemical or physical properties of the film, such as to modify the sensitivity of the film to EUV or enhancing etch resistance. Such optional materials may be introduced, such as by doping during vapor phase formation prior to deposition on the substrate, after deposition of the film, or both. In some embodiments, a gentle remote H₂ plasma may be introduced so as to replace some Sn—L bonds with Sn—H, which can increase reactivity of the resist under EUV.

In various embodiments, the EUV-patternable films are made and deposited on the substrate using vapor deposition equipment and processes among those known in the art. In such processes, the polymerized organometallic material is formed in vapor phase or in situ on the surface of the substrate. Suitable processes include, for example, chemical vapor deposition (CVD), atomic layer deposition (ALD), and ALD with a CVD component, such as a discontinuous, ALD-like process in which metal precursors and counter-reactants are separated in either time or space.

In general, methods comprise mixing a vapor stream of an organometallic precursor with a vapor stream of a counter-reactant so as to form a polymerized organometallic material and depositing the organometallic material onto the surface of the semiconductor substrate. As will be understood by one of ordinary skill in the art, the mixing and depositing aspects of the process may be concurrent, in a substantially continuous process.

In an exemplary continuous CVD process, two or more gas streams, in separate inlet paths, of organometallic precursor and source of counter-reactant are introduced to the deposition chamber of a CVD apparatus, where they mix and react in the gas phase, to form agglomerated polymeric materials (e.g., via metal-oxygen-metal bond formation). The streams may be introduced, for example, using separate injection inlets or a dual-plenum showerhead. The apparatus is configured so that the streams of organometallic precursor and counter-reactant are mixed in the chamber, allowing the organometallic precursor and counter-reactant to react to form a polymerized organometallic material. Without limiting the mechanism, function or utility of present technology, it is believed that the product from such vapor-phase reaction becomes heavier in molecular weight as metal atoms are crosslinked by counter-reactants, and is then condensed or otherwise deposited onto the substrate. In various embodiments, the steric hindrance of the bulky alkyl groups prevents the formation of densely packed network and produces porous, low density films.

The CVD process is generally conducted at reduced pressures, such as from 10 milliTorr to 10 Torr. In some embodiments, the process is conducted at from 0.5 to 2 Torr. The temperature of the substrate is preferably at or below the temperature of the reactant streams. For example, the substrate temperature may be from 0° C. to 250° C. or from ambient temperature (e.g., 23° C.) to 150° C. In various processes, deposition of the polymerized organometallic material on the substrate occurs at rates inversely proportional to surface temperature.

The thickness of the EUV-patternable film formed on the surface of the substrate may vary according to the surface characteristics, materials used, and processing conditions. In various embodiments, the film thickness may range from 0.5 nm to 100 nm and is preferably of sufficient thickness to absorb most of the EUV light under the conditions of EUV patterning. For example, the overall absorption of the resist film may be 30% or less (e.g., 10% or less, or 5% or less) so that the resist material at the bottom of the resist film is sufficiently exposed. In some embodiments, the film thickness is from 10 to 20 nm. Without limiting the mechanism, function, or utility of present technology, it is believed that, unlike wet, spin-coating processes of the art, the processes of the present technology have fewer restrictions on the surface adhesion properties of the substrate, and therefore can be applied to a wide variety of substrates. Moreover, as discussed above, the deposited films may closely conform to surface features, providing advantages in forming masks over substrates, such as substrates having underlying features, without “filling in” or otherwise planarizing such features.

In one or more embodiments, the first photoresist includes a photoacid generator. The photoacid generator is a compound capable of generating an acid upon irradiation with actinic rays or radiation. The photoacid generator may be selected from known compounds capable of generating an acid upon irradiation with actinic rays or radiation which are used for a photoinitiator for cationic photopolymerization, a photoinitiator for radical photopolymerization, a photodecoloring agent for dyes, a photodiscoloring agent, a microresist, or the like, and a mixture thereof can be used. Examples of the photoacid generator include a diazonium salt, a phosphonium salt, a sulfonium salt, an iodonium salt, imidosulfonate, oxime sulfonate, diazodisulfone, disulfone, and o-nitrobenzyl sulfonate.

Suitable photoacids include onium salts, for example, triphenylsulfonium trifhioromethanesulfonate, (p-tert-butoxyphenyl)diphenylsulfonium trifhioromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, and di-t-butyphenyliodonium camphorsulfonate. Non-ionic sulfonates and sulfonyl compounds are also known to function as photoacid generators, e.g., nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable non-polymerized photoacid generators are further described in U.S. Pat. No. 8,431,325 to Hashimoto et al. in column 37, lines 11-47 and columns 41-91. Other suitable sulfonate PAGs include sulfonated esters and sulfonyloxy ketones, nitrobenzyl esters, s-triazine derivatives, benzoin tosylate, t-butylphenyl α-(p-toluenesulfonyloxy)-acetate, and t-butyl α-(p-toluenesulfonyloxy)-acetate; as described in U.S. Pat. Nos. 4,189,323 and 8,431,325. PAGs that are onium salts typically comprise an anion having a sulfonate group or a non-sulfonate type group, such as a sulfonamidate group, a sulfonimidate group, a methide group, or a borate group.

The first photoresist may optionally comprise a plurality of PAGs. The plural PAGs may be polymeric, non-polymeric, or may include both polymeric and non-polymeric PAGs. Preferably, each of the plurality of PAGs is non-polymeric. Preferably, when a plurality of PAGs are used, a first PAG comprises a sulfonate group on the anion and a second PAG comprises an anion that is free of sulfonate groups, such anion containing for example, a sulfonamidate group, a sulfonimidate group, a methide group, or a borate group such as described above.

In one or more embodiments, the first photoresist optionally contains other additives, wherein other additives include at least one of a resin having at least either a fluorine atom or a silicon atom, a basic compound, a surfactant, an onium carboxylate, dye, a plasticizer, a photosensitizer, a light absorbent, an alkali-soluble resin, a dissolution inhibitor, and a compound for accelerating dissolution in a developer.

In one or more embodiments, the first photoresist provided on the substrate may have a sufficient thickness. A sufficient thickness for the first photoresist may range from about 300 to about 3000 Å.

In some embodiments, the first photoresist is stabilized prior to layering on the second photoresist. Various photoresist stabilization techniques, also known as freeze processes, have been proposed such as ion implantation, UV curing, thermal hardening, thermal curing and chemical curing. Techniques are described, for example, in US2008/0063985A1, US 2008/0199814A1 and US 2010/0330503A1.

At block 204 of method 200, a second photoresist is layered on the first photoresist. A substrate 302 layered with a first photoresist 304 and a second photoresist 306 is shown in FIG. 3A. The second photoresist may be layered on the first photoresist according to any suitable method known in the art such as, for example, spin-on deposition or vapor-phase treatment. The second photoresist may include a polymer and a photoacid generator. In one or more embodiments, the second resist may include a chemically amplified organic resist, metalorganic resist, or dry resist as previously described. The resist included in the second photoresist may be the same or different from the organic or metalorganic resist included in the first photoresist. For example, whereas the first photoresist may be an EUV photoresist, the second photoresist may be a DUV resist. In one or more embodiments, the second resist is an EUV resist.

After the second photoresist is layered on the first photoresist, the second photoresist may be exposed to a pattern of actinic radiation, as shown at block 206 of method 200. The actinic radiation may have any wavelength commonly used in lithography processes, such as, any UV wavelength. For example, the actinic radiation may have a wavelength ranging from 100 nm to 400 nm. Preferably, in one or more embodiments, the actinic radiation applied to the second photoresist has a wavelength ranging from 193 nm to 300 nm.

In order to impart a shape, or relief pattern, in the developed resist, a mask may be used to block a portion of the resist from the actinic radiation. After the actinic radiation is applied, the unexposed portion of the second photoresist may have a different solubility than the exposed portion of the second photoresist. A coated substrate in which the second resist has been exposed to a pattern of radiation is shown in FIG. 3B. As shown in FIG. 3B, the second photoresist is made up of an unexposed portion 306 and an exposed portion 307.

Subsequently, at block 208 of method 200, the second photoresist is rinsed with a resist developer to remove either the unexposed portion or the exposed portion and provide a relief pattern. A relief pattern provided when the unexposed portion of the photoresist remains after rinsing with a developer is a positive tone developed photoresist. In contrast, a relief pattern provided when the exposed portion of the photoresist remains after rinsing with a developer is a negative tone developed photoresist.

In some embodiments, the second photoresist is a positive tone developed (PTD) resist. In such embodiments, the second photoresist may include a polymer made from the above-described monomers, wherein any monomers including a reactive functional group are protected. As such, a PTD second photoresist may be organic soluble, and thus the relief pattern may be provided by rinsing with a resist developer that is basic. Suitable basic resist developers include quaternary ammonium hydroxides, such as tetramethylammonium hydroxide (TMAH).

In other embodiments, the second photoresist is a negative resist. In such embodiments, the relief pattern may include a polymer made from the above-described monomers, wherein any monomers including a reactive functional group are not protected. Exposure to actinic radiation results in crosslinking of the polymer in areas of exposure, rendering the polymer insoluble to developers. The unexposed, and thus uncrosslinked, areas can then be removed using an appropriate developer to form the relief pattern.

In yet other embodiments, the second photoresist is a negative tone developed (NTD) resist. Similar to PTD resists, NTD resists may include a polymer made from the above-described monomers, wherein any monomers including a reactive functional group are protected. As such, a NTD first resist may be organic soluble, however, instead of developing the exposed areas with a resist developer that is basic, the relief pattern may be provided by rinsing the first resist with a resist developer that includes an organic solvent. Suitable organic solvents that may be used as a resist developer include n-butyl acetate (NBA) and 2-heptanone.

The relief pattern of the second photoresist may include features separated by gaps. FIG. 3C shows a coated substrate including a second photoresist having such a relief pattern. In FIG. 3C, features 308 of a second photoresist 306 are separated by gaps 309. In one or more embodiments, the features of the relief pattern of the second photoresist may have a thickness of about 300 to 3000 Å. The gaps separating the features may leave portions of the first photoresist exposed.

Then, at block 210 of method 200, the first photoresist is exposed to a pattern of actinic radiation. The actinic radiation may have any wavelength commonly used in lithography processes, such as, any UV wavelength. For example, the actinic radiation may have a wavelength ranging from 10 nm to 400 nm. In one or more embodiments, the actinic radiation applied to the first photoresist has a different, shorter, wavelength than the actinic radiation applied to the second photoresist. Thus, the actinic radiation applied to the first photoresist may preferably have a wavelength ranging from 10 nm to 100 nm.

In one or more embodiments, the pattern of actinic radiation applied to the first photoresist is directed toward the first photoresist at a perpendicular angle, with respect to a nominal plane defined by the substrate (shown as nominal plane 100 in FIG. 1A). In such embodiments, a photomask may be combined with the existing relief pattern of the second photoresist to define the pattern of actinic radiation. An example of such combination is shown in FIG. 3D. As shown in FIG. 3D, the features 308 of the second photoresist 306 are used in combination with a photomask 311 to provide a specific pattern of actinic radiation and impart a latent pattern in the first photoresist. FIG. 3D shows that the latent pattern includes portions of the first photoresist 304 unexposed to the actinic radiation, and portions 310 of the first photoresist exposed to the actinic radiation. In particular, the exposed portion of the first photoresist may be between two features of the relief pattern of the second photoresist.

In one or more embodiments, the pattern of actinic radiation applied to the first photoresist is directed toward the first photoresist at an angle other than perpendicular with respect to a nominal plane defined by the substrate (shown as nominal plane 100 in FIG. 1B). For example, the pattern of actinic radiation may be directed toward the substrate at an angle between 10° and 80° relative to a nominal plane defined by the substrate. As such, in one or more embodiments, portions of the relief pattern of the second photoresist shadow portions of the first photoresist according to the exposure angle and height of structures of the second relief pattern. FIG. 3E shows a coated substrate that is exposed to actinic radiation having an angle other than perpendicular, with respect to a nominal plane defined by the substrate. As shown in FIG. 3E, the features 308 of the second photoresist 306 are used as a contact mask and a shadow mask with actinic radiation applied at an angle, to provide a latent pattern in the first photoresist. As described above, the latent pattern includes portions of the first photoresist 304 unexposed to the actinic radiation, and portions 310 of the first photoresist exposed to the actinic radiation. In particular, the exposed portion of the first photoresist may abut the features 308 of the second photoresist 306.

Finally, at block 212, the first photoresist is developed. As with the second photoresist, the first photoresist may be developed by rinsing with a resist developer to remove either the unexposed portion or the exposed portion and provide a relief pattern. The first photoresist may be a PTD photoresist or a NTD photoresist, and as such, may be developed using a basic or an organic developer. The basic and organic developers are as previously described.

In one or more embodiments, selective dry etching of the first photoresist may be performed exploiting differences related to the composition, extent of cross-linking, and film density. In some embodiments, the pattern is developed using a dry method to form a metal oxide-containing mask. Methods and equipment among those useful in such processes are described in U.S. Patent Application 62/782,578, Volosskiy et al, filed Dec. 20, 2018 (incorporated by reference herein). Such dry development processes can be done by using either a gentle plasma (high pressure, low power) or a thermal process while flowing a dry development chemistry such as BCl₃ (boron tricholoride) or other Lewis Acid. In some embodiments, BCl₃ is able to quickly remove the unexposed material, leaving behind a pattern of the exposed film that can be transferred into the underlying layers by plasma-based etch processes, for example conventional etch processes.

Plasma processes include transformer coupled plasma (TCP), inductively coupled plasma (ICP) or capacitively coupled plasma (CCP), employing equipment and techniques among those known in the art. For example, a process may be conducted at a pressure of >5 mT (e.g., >15 mT), at a power level of <1000 W (e.g., <500 W). Temperatures may be from 0 to 300° C. (e.g., 30 to 120° C.), at flow rate of 100 to 1000 standard cubic centimeters per minute (sccm), e.g., about 500 sccm, for from 1 to 3000 seconds (e.g., 10-600 seconds).

FIGS. 3F and G shows coated substrates at the end of method 200. FIG. 3F follows FIG. 3D, above. In FIG. 3F, features 308 of a second photoresist 306 form a contact mask on a first photoresist 304. After development, the first photoresist 304 has a relief pattern defined by a combination of the relief pattern of the second photoresist and the pattern of actinic radiation applied using a photomask. As such, small, and even sub-micron, gaps 312 are provided in the first photoresist 304.

FIG. 3G follows FIG. 3E, above. In FIG. 3G, features 308 of a second photoresist 306 form a contact mask on a first photoresist 304. By applying actinic radiation at an angle other than perpendicular, with respect to the substrate, the features 308 also act as a shadow mask. After development, the first photoresist 304 has a relief pattern defined by the contact mask and shadow mask resulting from the relief pattern of the second photoresist and the angle of actinic radiation applied. As such, small, and even sub-micron, gaps 312 are provided in the first photoresist 304.

Method 200 represents one possible embodiment and is not intended to limit the scope of the present invention. As will be appreciated by one of ordinary skill in the art, the present invention may encompass various alternative methods. In such alternate embodiments, the components and techniques used in the methods may be as previously described with reference to method 200.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

1. A method of patterning a substrate comprising:
providing a first photoresist on the substrate;
layering a second photoresist on the first photoresist;
exposing the second photoresist to a first pattern of actinic radiation;
developing the second photoresist such that portions of the second photoresist are removed providing gaps between features of the second photoresist, wherein the gaps provide uncovered portions of the first photoresist;
exposing the first photoresist to a second pattern of actinic radiation; and
developing the first photoresist such that portions of the uncovered portions of the first photoresist are removed providing gaps between the features of the first photoresist where a portion of the substrate is exposed.

2. The method of claim 1, wherein the first pattern of actinic radiation comprises a first wavelength and the second pattern of actinic radiation comprises a second wavelength.

3. The method of claim 2, wherein the first wavelength and the second wavelength are different.

4. The method of claim 2, wherein the second wavelength is shorter than the first wavelength.

5. The method of claim 2, wherein the first wavelength is in a range of from 200 nm to 300 nm.

6. The method of claim 2, wherein the second wavelength is in a range of from 10 nm to 100 nm.

7. The method of claim 1, wherein the second pattern of actinic radiation is directed to the first photoresist at an angle other than perpendicular.

8. The method of claim 1, wherein the second pattern of actinic radiation is directed to the first photoresist at an angle between 10° and 80° relative to the substrate.

9. The method of claim 1, wherein the second pattern of actinic radiation is directed to the first photoresist at a perpendicular angle relative to the substrate.

10. The method of claim 1, further comprising, before providing the first photoresist on the substrate, layering a target layer on the substrate.

11. The method of claim 10, wherein the target layer is a hardmask layer.

12. The method of claim 1, wherein the first photoresist and the second photoresist comprise different materials from each other.

13. The method of claim 1, wherein the first photoresist is an EUV resist and the second photoresist is a DUV resist.

14. The method of claim 1, wherein the first photoresist and the second photoresist comprise a same material as each other.

15. The method of claim 1, wherein the first photoresist is a chemically amplified organic polymer-based resist.

16. The method of claim 1, wherein the first photoresist is a metalorganic photoresist.

17. The method of claim 1, wherein the first photoresist is a dry resist.

18. The method of claim 1, wherein the second photoresist is a chemically amplified organic polymer-based resist.

19. The method of claim 1, wherein the second photoresist is a metalorganic resist.

20. The method of claim 1, wherein the second photoresist is a dry resist.

21. The method of claim 1, wherein the first pattern of actinic radiation has a wavelength of 193 nm.

22. The method of claim 1, wherein the first photoresist is a chemically amplified organic polymer-based resist comprising polyhydroxy styrene (PHS) and the second photoresist is a chemically amplified organic polymer-based resist comprising (meth)acrylate.

23. The method of claim 1, wherein the first pattern of actinic radiation has a wavelength of 193 nm and the second pattern of actinic radiation is EUV light.

24. The method of claim 1, wherein the first photoresist is a metalorganic resist or a dry resist comprising a metal and the second photoresist is a chemically amplified organic polymer-based resist comprising meth(acrylate).

25. (canceled)
